(19) United States
(12) Patent Application Publication
(10) Pub. No.: US 2024/0184203 A1
(43) Pub. Date: Jun. 6, 2024

(54) COMPOSITION FOR FORMING RESIST UNDERLAYER FILM, METHOD FOR MANUFACTURING SEMICONDUCTOR SUBSTRATE, AND METHOD FOR FORMING RESIST UNDERLAYER FILM

(71) Applicant: JSR CORPORATION, Tokyo (JP)

(72) Inventors: Yuki OZAKI, Tokyo (JP); Ryuichi SERIZAWA, Tokyo (JP); Kengo HIRASAWA, Tokyo (JP); Hiroki HIRABAYASHI, Tokyo (JP)

(73) Assignee: JSR CORPORATION, Tokyo (JP)

(21) Appl. No.: 18/422,098

(22) Filed: Jan. 25, 2024

Related U.S. Application Data
(63) Continuation-in-part of application No. PCT/JP2022/027130, filed on Jul. 8, 2022.

(30) Foreign Application Priority Data
Jul. 28, 2021 (JP) 2021-122884

(51) Int. Cl. G03F 7/039; G03F 7/00; G03F 7/004; G03F 7/038

(52) U.S. Cl. CPC G03F 7/0392; G03F 7/0035; G03F 7/0047; G03F 7/0048; G03F 7/0382

(57) ABSTRACT

A composition includes a metal compound, a polymer including a first structural unit represented by formula (1) and a second structural unit represented by formula (2), and a solvent. R¹ is a hydrogen atom or a substituted or unsubstituted monovalent hydrocarbon group having 1 to 20 carbon atoms; and R² is a substituted or unsubstituted monovalent hydrocarbon group having 1 to 20 carbon atoms. R³ is a hydrogen atom or a substituted or unsubstituted monovalent hydrocarbon group having 1 to 20 carbon atoms; L is a single bond or a divalent linking group; Ar is a group obtained by removing (n+1) hydrogen atoms from a substituted or unsubstituted aromatic ring having 6 to 20 ring members; R⁴ is a monovalent hydroxyalkyl group having 1 to 10 carbon atoms or a hydroxy group; and n is an integer of 0 to 8.

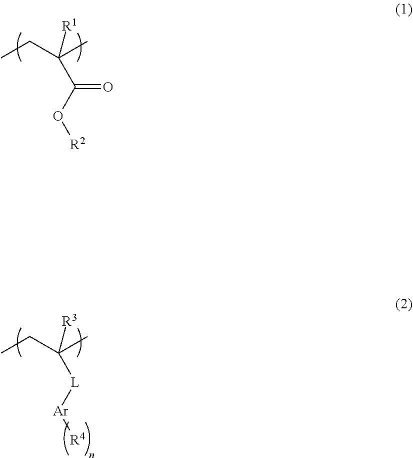

### CROSS-REFERENCE TO RELATED APPLICATIONS

The present application is a continuation-in-part application of International Patent Application No. PCT/JP2022/027130 filed Jul. 8, 2022, which claims priority to Japanese Patent Application No. 2021-122884 filed Jul. 28, 2021. The contents of these applications are incorporated herein by reference in their entirety.

### BACKGROUND OF THE DISCLOSURE

### Technical Field

The present disclosure relates to a composition for forming a resist underlayer film, a method for manufacturing a semiconductor substrate, and a method for forming a resist underlayer film.

### Background Art

In the manufacture of a semiconductor substrate and the like, a metal hardmask composition as a resist underlayer film has been proposed (see JP-A-2013-185155). In manufacturing a semiconductor substrate or the like, a clean track is commonly used. The clean track is a device that can consistently perform processing steps such as spin coating, edge bead removal (EBR), back rinsing, and firing. The EBR step is a step of forming a coating on a substrate (wafer) by spin coating and then removing the coating on an edge portion (peripheral portion) of the substrate with a removing liquid. This makes it possible to prevent staining a substrate carrying arm of the clean track. Stain of the carrying arm can cause defects and can reduce the yield of device manufacture. Examples of the removing liquid for use in the EBR step include a mixed liquid of propylene glycol monomethyl ether acetate and propylene glycol monoethyl ether (30:70, mass ratio), and the removing liquid is widely used in the EBR step for a resist film or a resist underlayer film (silicon-containing film, organic underlayer film, or metal hard mask).

### SUMMARY

According to an aspect of the present disclosure, a composition includes: a metal compound; a polymer including a first structural unit represented by formula (1) and a second structural unit represented by formula (2); and a solvent.

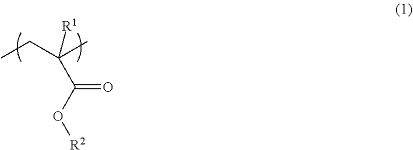

In the formula (1), R¹ is a hydrogen atom or a substituted or unsubstituted monovalent hydrocarbon group having 1 to 20 carbon atoms; and R² is a substituted or unsubstituted monovalent hydrocarbon group having 1 to 20 carbon atoms.

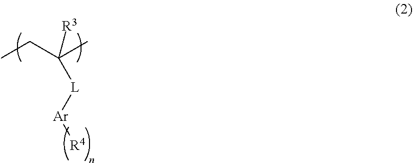

In the formula (2), R³ is a hydrogen atom or a substituted or unsubstituted monovalent hydrocarbon group having 1 to 20 carbon atoms; L is a single bond or a divalent linking group; Ar is a group obtained by removing (n+1) hydrogen atoms from a substituted or unsubstituted aromatic ring having 6 to 20 ring members; R⁴ is a monovalent hydroxyalkyl group having 1 to 10 carbon atoms or a hydroxy group; n is an integer of 0 to 8; and when n is 2 or more, a plurality of R⁴s are the same or different from each other.

According to another aspect of the present disclosure, a method for manufacturing a semiconductor substrate includes: applying a composition for forming a resist underlayer film directly or indirectly to a substrate to form a resist underlayer film; forming a resist pattern directly or indirectly on the resist underlayer film; and forming a pattern on the resist underlayer film by etching using the resist pattern as a mask. The composition for forming a resist underlayer film includes: a metal compound; a polymer including a first structural unit represented by formula (1) and a second structural unit represented by formula (2); and a solvent.

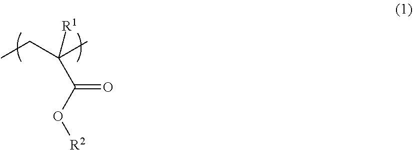

In the formula (1), R¹ is a hydrogen atom or a substituted or unsubstituted monovalent hydrocarbon group having 1 to 20 carbon atoms; and R2 is a substituted or unsubstituted monovalent hydrocarbon group having 1 to 20 carbon atoms.

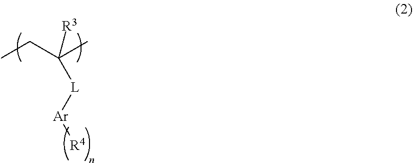

In the formula (2), R³ is a hydrogen atom or a substituted or unsubstituted monovalent hydrocarbon group having 1 to 20 carbon atoms; L is a single bond or a divalent linking group; Ar is a group obtained by removing (n+1) hydrogen atoms from a substituted or unsubstituted aromatic ring having 6 to 20 ring members; R⁴ is a monovalent hydroxyalkyl group having 1 to 10 carbon atoms or a hydroxy group; n is an integer of 0 to 8; and when n is 2 or more, a plurality of R⁴s are the same or different from each other.

According to a further aspect of the present disclosure, a method for forming a resist underlayer film includes applying a composition for forming a resist underlayer film directly or indirectly to a substrate. The composition for forming a resist underlayer film includes: a metal compound; a polymer including a first structural unit represented by formula (1) and a second structural unit represented by formula (2); and a solvent.

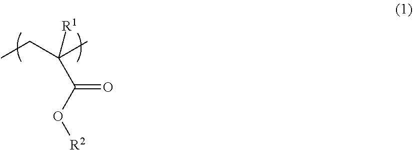

In the formula (1), R¹ is a hydrogen atom or a substituted or unsubstituted monovalent hydrocarbon group having 1 to 20 carbon atoms; and R² is a substituted or unsubstituted monovalent hydrocarbon group having 1 to 20 carbon atoms.

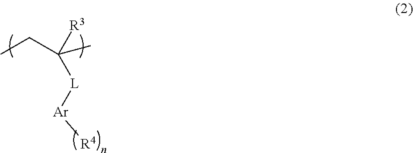

In the formula (2), R³ is a hydrogen atom or a substituted or unsubstituted monovalent hydrocarbon group having 1 to 20 carbon atoms; L is a single bond or a divalent linking group; Ar is a group obtained by removing (n+1) hydrogen atoms from a substituted or unsubstituted aromatic ring having 6 to 20 ring members; R⁴ is a monovalent hydroxyalkyl group having 1 to 10 carbon atoms or a hydroxy group; n is an integer of 0 to 8; and when n is 2 or more, a plurality of R⁴s are the same or different from each other.

### BRIEF DESCRIPTION OF THE DRAWINGS

FIG. 1 is an optical micrograph (10 magnifications) in a case where no removal unevenness was observed in the evaluation of wafer edge removability; and

FIG. 2 is an optical micrograph (10 magnifications) in a case where removal unevenness was observed in the evaluation of wafer edge removability.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Compositions for forming a resist underlayer film (metal hardmask compositions) are required to have good wafer edge removability of a resist underlayer film in the EBR step (smoothness of a boundary between a remaining portion and a removed portion of a metal hardmask) and film thickness variation (hump) inhibiting property as well as uniform coatability to a substrate surface.

In one embodiment, the present disclosure relates to a composition for forming a resist underlayer film, including:
a metal compound (hereinafter also referred to as “compound [A]”;
a polymer having a first structural unit represented by formula (1) (hereinafter also referred to as “structural unit (I)”) and a second structural unit represented by formula (2) (hereinafter also referred to as “structural unit (II)”) (hereinafter also referred to as “polymer [B]”); and a solvent (hereinafter also referred to as “solvent [C]”),

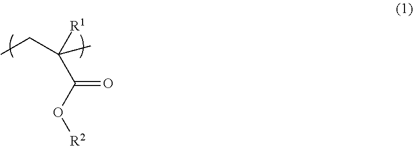

in the formula (1), R¹ is a hydrogen atom or a substituted or unsubstituted monovalent hydrocarbon group having 1 to 20 carbon atoms; and R² is a substituted or unsubstituted monovalent hydrocarbon group having 1 to 20 carbon atoms,

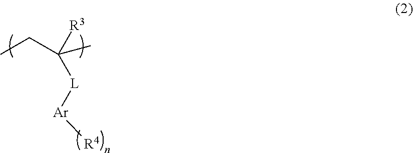

in the formula (2), R³ is a hydrogen atom or a substituted or unsubstituted monovalent hydrocarbon group having 1 to 20 carbon atoms; L is a single bond or a divalent linking group; Ar is a group obtained by removing (n+1) hydrogen atoms from a substituted or unsubstituted aromatic ring having 6 to 20 ring members; R⁴ is a monovalent hydroxyalkyl group having 1 to 10 carbon atoms or a hydroxy group; n is an integer of 0 to 8; and when n is 2 or more, a plurality of R⁴s are the same or different from each other.

In one embodiment, the present disclosure relates to a method for manufacturing a semiconductor substrate, the method including:
applying a composition for forming a resist underlayer film directly or indirectly to a substrate;
forming a resist pattern directly or indirectly on a resist underlayer film by applying the composition for forming a resist underlayer film; and
forming a pattern on the resist underlayer film by etching using the resist pattern as a mask,
wherein
the composition for forming a resist underlayer film includes:
a metal compound;
a polymer having a first structural unit represented by formula (1) and a second structural unit represented by formula (2); and
a solvent,

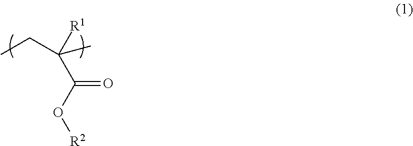

in the formula (1), R¹ is a hydrogen atom or a substituted or unsubstituted monovalent hydrocarbon group having 1 to 20 carbon atoms; and R² is a substituted or unsubstituted monovalent hydrocarbon group having 1 to 20 carbon atoms,

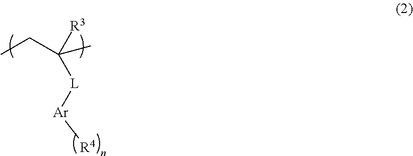

in the formula (2), R³ is a hydrogen atom or a substituted or unsubstituted monovalent hydrocarbon group having 1 to 20 carbon atoms; L is a single bond or a divalent linking group; Ar is a group obtained by removing (n+1) hydrogen atoms from a substituted or unsubstituted aromatic ring having 6 to 20 ring members; R⁴ is a monovalent hydroxyalkyl group having 1 to 10 carbon atoms or a hydroxy group; n is an integer of 0 to 8; and when n is 2 or more, a plurality of R⁴s are the same or different from each other.

In another embodiment, the present disclosure relates to a method for forming a resist underlayer film, the method including applying a composition for forming a resist underlayer film directly or indirectly to a substrate,
wherein
the composition for forming a resist underlayer film includes:
a metal compound;
a polymer having a first structural unit represented by formula (1) and a second structural unit represented by formula (2); and
a solvent,

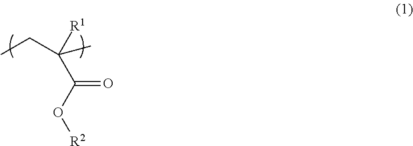

in the formula (1), R¹ is a hydrogen atom or a substituted or unsubstituted monovalent hydrocarbon group having 1 to 20 carbon atoms; and R² is a substituted or unsubstituted monovalent hydrocarbon group having 1 to 20 carbon atoms,

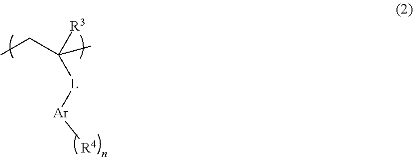

in the formula (2), R³ is a hydrogen atom or a substituted or unsubstituted monovalent hydrocarbon group having 1 to 20 carbon atoms; L is a single bond or a divalent linking group; Ar is a group obtained by removing (n+1) hydrogen atoms from a substituted or unsubstituted aromatic ring having 6 to 20 ring members; R⁴ is a monovalent hydroxyalkyl group having 1 to 10 carbon atoms or a hydroxy group; n is an integer of 0 to 8; and when n is 2 or more, a plurality of R⁴s are the same or different from each other.

The composition for forming a resist underlayer film of the embodiment is superior in all of coatability, wafer edge removability during the EBR step, and hump inhibiting property. By the method for manufacturing a semiconductor substrate of the embodiment, a resist underlayer film is formed using a composition for forming a resist underlayer film that is superior in all of coatability, wafer edge removability during the EBR step, and hump inhibiting property, so that a high-quality semiconductor substrate can be efficiently manufactured. By the method for forming a resist underlayer film of the embodiment, a desired resist underlayer film can be efficiently formed because a composition for forming a resist underlayer film superior in all of coatability, wafer edge removability during the EBR step, and hump inhibiting property is used. Therefore, these can suitably be used for, for example, manufacturing semiconductor devices expected to be further microfabricated in the future.

Hereinafter, a composition for forming a resist underlayer film, a method for manufacturing a semiconductor substrate, and a method for forming a resist underlayer film according to each embodiment of the present disclosure will be described in detail. The description on the composition for forming a resist underlayer film will be appropriately developed in the course of describing the method for manufacturing a semiconductor substrate. Combinations of suitable modes in the embodiments are also preferred.

### Method for Manufacturing Semiconductor Substrate

The method for manufacturing a semiconductor substrate includes: applying a composition for forming a resist underlayer film (hereinafter also referred to as a “composition”) directly or indirectly to a substrate (hereinafter also referred to as an “applying step”); forming a resist pattern directly or indirectly on the resist underlayer film formed by the applying step (hereinafter also referred to as a “resist pattern forming step”); and forming a pattern on the resist underlayer film by etching using the resist pattern as a mask (hereinafter also referred to as an “etching step”).

By the method for manufacturing a semiconductor substrate, a resist underlayer film is formed using a composition for forming a resist underlayer film that is superior in all of coatability, wafer edge removability during the EBR step, and hump inhibiting property, so that a high-quality semiconductor substrate can be efficiently manufactured.

If necessary, the method for manufacturing a semiconductor substrate may further include, before the resist pattern forming step, forming an organic underlayer film directly or indirectly on the substrate having a resist underlayer film formed in the applying step (hereinafter also referred to as an “organic underlayer film forming step).

If necessary, the method for manufacturing a semiconductor substrate may further include, before the resist pattern forming step, forming a silicon-containing film directly or indirectly on the substrate having a resist underlayer film formed in the applying step (hereinafter also referred to as a “silicon-containing film forming step).

Hereinafter, description will be made to the composition for forming a resist underlayer film to be used for the method for manufacturing a semiconductor substrate, and respective steps in the case of including an organic underlayer film forming step and a silicon-containing film forming step, which are optional steps.

### Composition for Forming a Resist Underlayer Film

The composition for forming a resist underlayer film (this composition is hereinafter also simply referred to as “composition [A]”) includes a compound [A], a polymer [B], and a solvent [C]. The composition may further include other optional components as long as the effect of the present invention is not impaired.

### Compound [A]

The compound [A] is a compound including a metal atom and an oxygen atom. Examples of the metal atom constituting the compound [A] include metal atoms of Groups 3 to 16 of the periodic table (excluding silicon atom). The compound [A] may have one kind or two or more kinds of metal atom.

Examples of Group 3 metal atom include scandium, yttrium, lanthanum, and cerium;

examples of Group 4 metal atom include titanium, zirconium, and hafnium;

examples of Group 5 metal atom include vanadium, niobium, and tantalum;

examples of Group 6 metal atom include chromium, molybdenum, and tungsten;

examples of Group 7 metal atom include manganese and rhenium;

examples of Group 8 metal atom include iron, ruthenium, and osmium;

examples of Group 9 metal atom include cobalt, rhodium, and iridium;

examples of Group 10 metal atom include nickel, palladium, and platinum;

examples of Group 11 metal atom include copper, silver, and gold;

examples of Group 12 metal atom include zinc, cadmium, and mercury;

examples of Group 13 metal atom include aluminum, gallium, and indium;

examples of Group 14 metal atom include germanium, tin, and lead;

examples of Group 15 metal atom include antimony and bismuth; and

examples of Group 16 metal atom include tellurium.

As the metal atom constituting the compound [A], metal atoms of Group 3 to Group 16 are preferable, metal atoms of Group 4 to Group 14 are more preferable, metal atoms of Group 4, Group 5, and Group 14 are still more preferable, and metal atoms of Group 4 are particularly preferable. Specifically, titanium, zirconium, hafnium, tantalum, tungsten, tin, or a combination thereof is more preferable.

As the component (hereinafter also referred to as “compound [x]”) other than the metal atom constituting the compound [A], an organic acid (hereinafter also referred to as “organic acid [a]”) , a hydroxy acid ester, a B-diketone, an α, α-dicarboxylic acid ester, and an amine compound are preferable. Herein, the “organic acid” refers to any organic compound that exhibits acidity, and the “organic compound” refers to any compound having at least one carbon atom.

Examples of the organic acid [a] include carboxylic acids, sulfonic acids, sulfinic acids, organic phosphinic acids, organic phosphonic acids, phenols, enols, thiols, acid imides, oximes, and sulfonamides.

Examples of the carboxylic acids include monocarboxylic acids such as formic acid, acetic acid, propionic acid, butanoic acid, pentanoic acid, hexanoic acid, heptanoic acid, octanoic acid, nonanoic acid, decanoic acid, 2-ethylhexanoic acid, oleic acid, acrylic acid, methacrylic acid, trans-2, 3-dimethylacrylic acid, stearic acid, linoleic acid, linolenic acid, arachidonic acid, salicylic acid, benzoic acid, p-aminobenzoic acid, monochloroacetic acid, dichloroacetic acid, trichloroacetic acid, trifluoroacetic acid, pentafluoropropionic acid, gallic acid, and shikimic acid; dicarboxylic acids such as oxalic acid, malonic acid, maleic acid, methylmalonic acid, fumaric acid, adipic acid, sebacic acid, phthalic acid, and tartaric acid; and carboxylic acids having three or more carboxy groups such as citric acid.

Examples of the sulfonic acids include benzenesulfonic acid and p-toluenesulfonic acid.

Examples of the sulfinic acids include benzenesulfinic acid and p-toluenesulfinic acid.

Examples of the organic phosphinic acids include diethylphosphinic acid, methylphenylphosphinic acid, and diphenylphosphinic acid.

Examples of the organic phosphonic acids include methylphosphonic acid, ethylphosphonic acid, t-butylphosphonic acid, cyclohexylphosphonic acid, and phenylphosphonic acid.

Examples of the phenols include monohydric phenols such as phenol, cresol, 2, 6-xylenol, and naphthol;

dihydric phenols such as catechol, resorcinol, hydroquinone, and 1,2-naphthalenediol; and

trihydric or higher phenols such as pyrogallol and 2, 3, 6-naphthalenetriol.

Examples of the enols include 2-hydroxy-3-methyl-2-butene and 3-hydroxy-4-methyl-3-hexene.

Examples of the thiols include mercaptoethanol and mercaptopropanol.

Examples of the acid imides include carboxylic acid imides such as maleimide and succinimide, and sulfonic acid imides such as di (trifluoromethanesulfonic acid) imide and di (pentafluoroethanesulfonic acid) imide.

Examples of the oximes include aldoximes such as benzaldoxime and salicylaldoxime, and ketoximes such as diethylketoxime, methylethylketoxime, and cyclohexanone oxime.

Examples of the sulfonamides include methylsulfonamide, ethylsulfonamide, benzenesulfonamide, and toluenesulfonamide.

As the organic acid [a], carboxylic acids are preferable, monocarboxylic acids are more preferable, and methacrylic acid and benzoic acid are still more preferable.

Examples of the hydroxy acid esters include glycolic acid esters, lactic acid esters, 2-hydroxycyclohexane-1-carboxylic acid esters, and salicylic acid esters.

Examples of the β-diketones include 2, 4-pentanedione, 3-methyl-2, 4-pentanedione, and 3-ethyl-2, 4-pentanedione.

Examples of the β-ketoesters include acetoacetic acid esters, α-alkyl-substituted acetoacetic acid esters, β-ketopentanoic acid esters, benzoylacetic acid esters, and 1,3-acetonedicarboxylic acid esters.

Examples of the amine compounds include diethanolamine and triethanolamine.

As the compound [A], metal compounds composed of a metal atom and an organic acid [a] are preferable, metal compounds composed of a Group 4, Group 5 or Group 14 metal atom and a carboxylic acid are more preferable, and metal compounds composed of titanium, zirconium, hafnium, tantalum, tungsten or tin and methacrylic acid or benzoic acid are still more preferable.

The compound [A] may include one or two or more of the metal compound.

The compound [A] may include one or two or more of the organic acid [a].

The lower limit of the content ratio of the compound [A] accounting for in all components contained in the composition is preferably 2% by mass, more preferably 4% by mass, and still more preferably 6% by mass. The upper limit of the content ratio is preferably 30% by mass, more preferably 20% by mass, and still more preferably 15% by mass.

### Method for Synthesizing Compound [A]

The compound [A] can be synthesized by, for example, a method of performing a hydrolysis-condensation reaction using a metal-containing compound [b], a method of performing a ligand substitution reaction using a metal-containing compound [b], or the like. Herein, the “hydrolysis-condensation reaction” refers to a reaction in which the hydrolyzable group of the metal-containing compound [b] is hydrolyzed to be converted into —OH, and the resulting two —OH groups are dehydration-condensed to form —O—.

### Metal-Containing Compound [b]

The metal-containing compound [b] is a metal compound (b1) having a hydrolyzable group, a hydrolysate of a metal compound (b1) having a hydrolyzable group, a hydrolysis-condensate of a metal compound (b1) having a hydrolyzable group, or a combination thereof. The metal compound (b1) may be used singly or two or more thereof may be used in combination.

Examples of the hydrolyzable group include a halogen atom, an alkoxy group, and an acyloxy group.

Examples of the halogen atom include a fluorine atom, a chlorine atom, a bromine atom, and an iodine atom.

Examples of the alkoxy group include a methoxy group, an ethoxy group, a n-propoxy group, an isopropoxy group, and a n-butoxy group.

Examples of the acyloxy group include an acetoxy group, an ethylyloxy group, a propionyloxy group, a butyryloxy group, a t-butyryloxy group, a t-amylyloxy group, an n-hexanecarbonyloxy group, and an n-octanecarbonyloxy group.

As the hydrolyzable group, an alkoxy group and an acyloxy group are preferable, and an isopropoxy group and an acetoxy group are more preferable.

When the metal-containing compound [b] is a hydrolysis-condensate of a metal compound (b1), the hydrolysis-condensate of the metal compound (b1) may be a hydrolysis-condensate of the metal compound (b1) having a hydrolyzable group and a compound containing a metalloid atom as long as the effect of the present invention is not impaired. That is, the hydrolysis-condensate of the metal compound (b1) may contain a metalloid atom as long as the effect of the present invention is not impaired. Examples of the metalloid atom include silicon, boron, germanium, antimony, and tellurium. The content of the metalloid atom in the hydrolysis-condensate of the metal compound (b1) is usually less than 50 atom % based on the total of the metal atom and the metalloid atom in the hydrolysis-condensate. The upper limit of the content of the metalloid atom is preferably 30 atom8, more preferably 10 atom% based on the total of the metal atom and the metalloid atom in the hydrolysis-condensate.

Examples of the metal compound (b1) include a compound represented by formula (a) (hereinafter also referred to as “compound [m]”).

LₐMY_{b} (α)

In the formula (α), M is a metal atom. L is a ligand. a is an integer of 0 to 2. When a is 2, a plurality of L's are the same or different. Y is a hydrolyzable group selected from among a halogen atom, an alkoxy group, and an acyloxy group. b is an integer of 2 to 6. The plurality of Y's may be the same or different. Note that L is a ligand that does not correspond to Y.

Examples of the metal atom represented by M include metal atoms the same as those disclosed as examples of the metal atom constituting the metal compound contained in the compound [A].

Examples of the ligand represented by L include a monodentate ligand and a multidentate ligand.

Examples of the monodentate ligand include a hydroxo ligand, a carboxy ligand, an amide ligand, and ammonia.

Examples of the amide ligand include an unsubstituted amide ligand (NH₂), a methylamide ligand (NHMe), a dimethylamide ligand (NMe₂), a diethylamide ligand (NEt₂), and a dipropylamide ligand (NPr₂).

Examples of the multidentate ligand include hydroxy acid esters, β-diketones, β-ketoesters, β-dicarboxylic acid esters, hydrocarbons having a π bond, and diphosphines.

Examples of the hydroxy acid esters include glycolic acid esters, lactic acid esters, 2-hydroxycyclohexane-1-carboxylic acid esters, and salicylic acid esters.

Examples of the β-diketones include 2, 4-pentanedione, 3-methyl-2, 4-pentanedione, and 3-ethyl-2, 4-pentanedione.

Examples of the β-ketoesters include acetoacetic acid esters, α-alkyl-substituted acetoacetic acid esters, β-ketopentanoic acid esters, benzoylacetic acid esters, and 1,3-acetonedicarboxylic acid esters.

Examples of the β-dicarboxylic acid esters include malonic diesters, α-alkyl-substituted malonic diesters, α-cycloalkyl-substituted malonic diesters, and α-aryl-substituted malonic diesters.

Examples of the hydrocarbons having a π bond include
chain olefins such as ethylene and propylene;
cyclic olefins such as cyclopentene, cyclohexene, and norbornene;
chain dienes such as butadiene and isoprene;
cyclic dienes such as cyclopentadiene, methylcyclopentadiene, pentamethylcyclopentadiene, cyclohexadiene, and norbornadiene; and
aromatic hydrocarbons such as benzene, toluene, xylene, hexamethylbenzene, naphthalene, and indene.

Examples of the diphosphines include 1,1-bis (diphenylphosphino) methane, 1,2-bis (diphenylphosphino) ethane, 1, 3-bis (diphenylphosphino) propane, 2, 2′-bis (diphenylphosphino)-1, 1′-binaphthyl, and 1, 1′-bis (diphenylphosphino) ferrocene.

Examples of the halogen atom represented by Y include a fluorine atom, a chlorine atom, a bromine atom, and an iodine atom.

Examples of the alkoxy group represented by Y include a methoxy group, an ethoxy group, a propoxy group, and a butoxy group.

Examples of the acyloxy group represented by Y include an acetoxy group, an ethylyloxy group, a butyryloxy group, a t-butyryloxy group, a t-amylyloxy group, an n-hexanecarbonyloxy group, and an n-octanecarbonyloxy group.

As Y, an alkoxy group and an acyloxy group are preferable, and an isopropoxy group and an acetoxy group are more preferable.

As b, 3 and 4 are preferable, and 4 is more preferable.

As the metal-containing compound [b], metal alkoxides subjected to neither hydrolysis nor hydrolysis-condensation and metal acyloxides subjected to neither hydrolysis nor hydrolysis-condensation are preferable.

Examples of the metal-containing compound [b] include zirconium tetra-n-butoxide, zirconium tetra-n-propoxide, zirconium tetraisopropoxide, hafnium tetraethoxide, indium triisopropoxide, hafnium tetraisopropoxide, hafnium tetra-n-propoxide, hafnium tetra-n-butoxide, tantalum pentaethoxide, tantalum penta-n-butoxide, tungsten pentamethoxide, tungsten penta-n-butoxide, tungsten hexaethoxide, tungsten hexa-n-butoxide, iron chloride, zinc diisopropoxide, zinc acetate dihydrate, tetrabutyl orthotitanate, titanium tetra-n-butoxide, titanium tetra-n-propoxide, zirconium di-n-butoxide bis (2, 4-pentanedionate), titanium tri-n-butoxide stearate, bis (cyclopentadienyl) hafnium dichloride, bis (cyclopentadienyl) tungsten dichloride, diacetato [(S)-(-)-2, 2′-bis (diphenylphosphino) -1, 1′-binaphthyl]ruthenium, dichloro [ethylenebis (diphenylphosphine)]cobalt, titanium butoxide oligomer, aminopropyltrimethoxytitanium, aminopropyltriethoxyzirconium, 2-(3,4-epoxycyclohexyl) ethyltrimethoxyzirconium, γ-glycidoxypropyltrimethoxyzirconium, 3-isocyanopropyltrimethoxyzirconium, 3-isocyanopropyltriethoxyzirconium, triethoxymono (acetylacetonato) titanium, tri-n-propoxymono (acetylacetonato) titanium, tri-isopropoxymono (acetylacetonato) titanium, triethoxymono (acetylacetonato) zirconium, tri-n-propoxymono (acetylacetonato) zirconium, tri-isopropoxymono (acetylacetonato) zirconium, diisopropoxybis (acetylacetonato) titanium, di-n-butoxybis (acetylacetonato) titanium, di-n-butoxybis (acetylacetonato) zirconium, tri (3-methacryloxypropyl) methoxyzirconium, tri (3-acryloxypropyl) methoxyzirconium, tin tetraisopropoxide, tin tetra-n-butoxide, lanthanum oxide, and yttrium oxide.

Among them, metal alkoxides and metal acyloxides are preferable, metal alkoxides are more preferable, and alkoxides of titanium, zirconium, hafnium, tantalum, tungsten, and tin are still more preferable.

When an organic acid is used for the synthesis of the compound [A], the lower limit of the amount of the organic acid used is preferably 1 mol, more preferably 2 mol, per mole of the metal-containing compound [b]. On the other hand, the upper limit of the amount of the organic acid used is preferably 6 mol, more preferably 5 mol, per mole of the metal-containing compound [b].

In the synthesis reaction of the compound [A], in addition to the metal compound (b1) and the organic acid [a], a compound capable of serving as a multidentate ligand represented by L in the compound of the formula (α), a compound capable of serving as a bridging ligand, or the like may be added. Examples of the compound capable of serving as a bridging ligand include compounds having a plurality of hydroxy groups, isocyanate groups, amino groups, ester groups, or amide groups.

Examples of the method of performing the hydrolysis-condensation reaction using the metal-containing compound [b] include a method of subjecting the metal-containing compound [b] to a hydrolysis-condensation reaction in a solvent containing water. In this case, another compound having a hydrolyzable group may be added, as necessary. The lower limit of the amount of water used in the hydrolysis-condensation reaction is preferably 0.2 times mol, more preferably 1 time mol, and still more preferably 3 times mol, in the number of moles, based on the hydrolyzable group of the metal-containing compound [b] and the like. The upper limit of the amount of water is preferably 20 times mol, more preferably 15 times mol, and still more preferably 10 times mol.

Examples of the method of performing the ligand substitution reaction using the metal-containing compound [b] include a method involving mixing the metal-containing compound [b] and the organic acid [a]. In this case, the metal-containing compound [b] and the organic acid [a] may be mixed in a solvent, or may be mixed without using a solvent. In the mixing, a base such as triethylamine may be added, as necessary. The addition amount of the base is, for example, 1 part by mass or more and 200 parts by mass or less based on 100 parts by mass of the total use amount of the metal-containing compound [b] and the organic acid [a].

The solvent to be used in the synthesis reaction of the compound [A] (hereinafter also referred to as “solvent [d]”) is not particularly limited, and for example, the same solvents as those disclosed as examples of the solvent [C] described later can be used. Among them, alcohol-based solvents, ether-based solvents, ester-based solvents, and hydrocarbon-based solvents are preferable, alcohol-based solvents, ether-based solvents, and ester-based solvents are more preferable, monoalcohol-based solvents, polyhydric alcohol partial ether-based solvents, and polyhydric alcohol partial ether carboxylate-based solvents are still more preferable, and ethanol, n-propanol, isopropanol, 1-butanol, propylene glycol monoethyl ether, and propylene glycol monoethyl ether acetate are particularly preferable.

When the solvent [d] is used in the synthesis reaction of the compound [A], the solvent used may be removed after the reaction, but may be used as it is as the solvent [C] of the composition for forming a resist underlayer film without being removed after the reaction.

### Polymer [B]

The polymer [B] has a structural unit (I) and a structural unit (II) (however, a structural unit corresponding to the structural unit (II) is excluded from the structural unit (I)). The polymer [B] may contain a structural unit other than the structural unit (I) and the structural unit (II) (hereinafter also simply referred to as “other structural unit”). The polymer [B] may have one type or two or more types of the respective structural units.

### Structural Unit (I)

The structural unit (I) is a structural unit represented by formula (1). Owing to that the polymer [B] has the structural unit (I), the fluidity of the composition can be improved, and as a result, the wafer edge removability and the hump inhibiting property during the EBR step of a resist underlayer film formed of the composition can be improved.

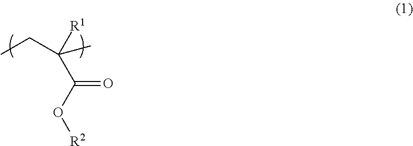

In the formula (1), R¹ is a hydrogen atom or a substituted or unsubstituted monovalent hydrocarbon group having 1 to 20 carbon atoms. R² is a substituted or unsubstituted monovalent hydrocarbon group having 1 to 20 carbon atoms.

In the present specification, the “hydrocarbon group” includes a chain hydrocarbon group, an alicyclic hydrocarbon group, and an aromatic hydrocarbon group. The “hydrocarbon group” includes a saturated hydrocarbon group and an unsaturated hydrocarbon group. The “chain hydrocarbon group” means a hydrocarbon group that does not include a cyclic structure and is composed only of a chain structure, and includes both a linear hydrocarbon group and a branched hydrocarbon group. The “alicyclic hydrocarbon group” means a hydrocarbon group that includes only an alicyclic structure as a ring structure and does not include an aromatic ring structure, and includes both a monocyclic alicyclic hydrocarbon group and a polycyclic alicyclic hydrocarbon group. However, it is not necessary for the alicyclic hydrocarbon group to be composed only of an alicyclic structure, and the alicyclic hydrocarbon group may include a chain structure in a part thereof. The “aromatic hydrocarbon group” means a hydrocarbon group that includes an aromatic ring structure as a ring structure. However, it is not necessary for the aromatic hydrocarbon group to be composed only of an aromatic ring structure, and the aromatic hydrocarbon group may include a chain structure or an alicyclic structure in a part thereof.

Examples of the unsubstituted monovalent hydrocarbon group having 1 to 20 carbon atoms in R¹ or R² include unsubstituted monovalent chain hydrocarbon groups having 1 to 20 carbon atoms, unsubstituted monovalent alicyclic hydrocarbon groups having 3 to 20 carbon atoms, and unsubstituted monovalent aromatic hydrocarbon groups having 6 to 20 carbon atoms.

Examples of the unsubstituted monovalent chain hydrocarbon groups having 1 to 20 carbon atoms include alkyl groups such as a methyl group, an ethyl group, a propyl group, a butyl group, and a pentyl group; alkenyl groups such as an ethenyl group, a propenyl group, and a butenyl group; and alkynyl groups such as an ethynyl group, a propynyl group, and a butynyl group.

Examples of the unsubstituted monovalent alicyclic hydrocarbon groups having 3 to 20 carbon atoms include cycloalkyl groups such as a cyclopentyl group and a cyclohexyl group; cycloalkenyl groups such as a cyclopropenyl group, a cyclopentenyl group, and a cyclohexenyl group; bridged cyclic hydrocarbon groups such as a norbornyl group and an adamantyl group.

Examples of the unsaturated monovalent aromatic hydrocarbon groups having 6 to 20 carbon atoms include aryl groups such as a phenyl group and a naphthyl group; and aralkyl groups such as a benzyl group, a phenethyl group, and a naphthylmethyl group.

Examples of the substituent in R¹ or R² include monovalent chain hydrocarbon groups having 1 to 10 carbon atoms; halogen atoms such as a fluorine atom, a chlorine atom, a bromine atom, and an iodine atom; alkoxy groups such as a methoxy group, an ethoxy group, and a propoxy group; alkoxycarbonyl groups such as a methoxycarbonyl group and an ethoxycarbonyl group; alkoxycarbonyloxy groups such as a methoxycarbonyloxy group and an ethoxycarbonyloxy group; acyl groups such as a formyl group, an acetyl group, a propionyl group, and a butyryl group; a cyano group, a nitro group, and a hydroxy group.

As R¹, a hydrogen atom or a substituted or unsubstituted monovalent chain hydrocarbon group having 1 to 20 carbon atoms is preferable, a hydrogen atom or an unsubstituted monovalent hydrocarbon group having 1 to 20 carbon atoms is more preferable, and a hydrogen atom or a methyl group is still more preferable.

As R², a substituted monovalent chain hydrocarbon group having 1 to 20 carbon atoms is preferable, a fluorine atom-substituted monovalent chain hydrocarbon group having 1 to 20 carbon atoms is more preferable, and a hexafluoroisopropyl group, a 2,2,2-trifluoroethyl group, or a 3, 3, 4, 4, 5, 5, 6, 6-octafluorohexyl group is still more preferable. In this case, the wafer edge removability and the hump inhibiting property during the EBR step of a resist underlayer film to be formed of the composition can be further improved. In the present specification, the “fluorine atom-substituted monovalent chain hydrocarbon group having 1 to 20 carbon atoms” means a group in which a part or all of hydrogen atoms of a chain hydrocarbon group are substituted with fluorine atoms.

The lower limit of the content ratio of the structural unit (I) accounting for in all structural units constituting the polymer [B] is preferably 10 mol %, more preferably 20 mol %, and still more preferably 30 mol %. The upper limit of the content ratio is preferably 90 mol %, more preferably 80 mol %, and still more preferably 70 mol %. When the content ratio of the structural unit (I) is in the above range, the wafer edge removability and the hump inhibiting property during the EBR step of a resist underlayer film to be formed of the composition can be further improved.

### Structural unit (II)

The structural unit (II) is a structural unit represented by formula (2). Owing to that the polymer [B] has the structural unit (II), compatibility with the compound [A] and affinity with a substrate can be improved, and as a result, the coatability of the composition can be improved.

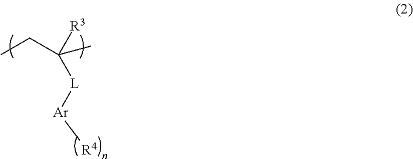

In the formula (2), R³ is a hydrogen atom or a substituted or unsubstituted monovalent hydrocarbon group having 1 to 20 carbon atoms. L is a single bond or a divalent linking group. Ar is a group obtained by removing (n+1) hydrogen atoms from a substituted or unsubstituted aromatic ring having 6 to 20 ring members. R⁴ is a monovalent hydroxyalkyl group having 1 to 10 carbon atoms or a hydroxy group. n is an integer of 0 to 8. When n is 2 or more, a plurality of R⁴s are the same or different from each other.

Examples of the monovalent unsubstituted hydrocarbon group having 1 to 20 carbon atoms in R3 include groups the same as those disclosed as examples of the unsubstituted monovalent hydrocarbon group having 1 to 20 carbon atoms in R¹ of the above formula (1).

Examples of the substituent in R³ include the same groups as those disclosed as examples of the substituent in RI of the above formula (1).

As R³, a hydrogen atom or a substituted or unsubstituted monovalent chain hydrocarbon group having 1 to 20 carbon atoms is preferable, a hydrogen atom or an unsubstituted monovalent chain hydrocarbon group having 1 to 20 carbon atoms is more preferable, and a hydrogen atom or a methyl group is still more preferable.

Examples of the divalent linking group in L include divalent hydrocarbon groups having 1 to 10 carbon atoms, —COO—, —CO—, —O—, and —CONH—.

A single bond is preferable as L.

Examples of the unsaturated aromatic ring having 6 to 20 ring members in Ar include aromatic hydrocarbon rings such as a benzene ring, a naphthalene ring, an anthracene ring, an indene ring, and a pyrene ring; and aromatic heterocycles such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, and a triazine ring. Among them, aromatic hydrocarbon rings are preferable. In the present specification, the term “ring members” refers to the number of the atoms constituting the ring, and in the case of a polycyclic ring, it refers to the number of the atoms constituting the polycyclic ring.

Examples of the substituent in Ar include the same groups as those disclosed as examples of the substituent in R¹ of the above formula (1). However, R⁴ described later is not regarded as a substituent in Ar.

As Ar, a group obtained by removing (n+1) hydrogen atoms from an unsaturated aromatic ring having 6 to 20 ring members is preferable, a group obtained by removing (n+1) hydrogen atoms from an unsaturated aromatic hydrocarbon ring having 6 to 20 ring members is more preferable, and a group obtained by removing (n+1) hydrogen atoms from an unsubstituted benzene ring is still more preferable.

The monovalent hydroxyalkyl group having 1 to 10 carbon atoms in R⁴ is a group in which a part or all of hydrogen atoms of a monovalent alkyl group having 1 to 10 carbon atoms are substituted with hydroxy groups.

As R⁴, a monovalent hydroxyalkyl group having 1 to 10 carbon atoms is preferable, a monovalent monohydroxyalkyl group having 1 to 10 carbon atoms is more preferable, and a monohydroxymethyl group is still more preferable. Owing to that R⁴ is the above group, the flatness of a resist underlayer film formed of the composition can be further improved.

n is preferably 1 to 5, more preferably 1 to 3, still more preferably 1 or 2, and particularly preferably 1.

The lower limit of the content ratio of the structural unit (II) accounting for in all structural units constituting the polymer [B] is preferably 10 mol %, more preferably 20 mol %, and still more preferably 30 mol %. The upper limit of the content ratio is preferably 90 mol %, more preferably 80 mol %, and still more preferably 70 mol %. When the content ratio of the structural unit (II) is within the above range, the coatability of the composition can be further improved.

### Other Structural Unit

Examples of the other structural unit include a structural unit derived from a (meth) acrylic acid ester, a structural unit derived from a (meth) acrylic acid, and a structural unit derived from an acenaphthylene compound.

When the polymer [B] has the other structural unit, the upper limit of the content ratio of the other structural unit accounting for in all structural units constituting the polymer [B] is preferably 20 mol %, and more preferably 5 mol %.

The lower limit of the Mw of the polymer [B] is preferably 1,000, more preferably 2, 000, still more preferably 3,000, and particularly preferably 3,500. The upper limit of the Mw is preferably 100, 000, more preferably 50, 000, still more preferably 30,000, and particularly preferably 20,000. Owing to that the Mw of the polymer [B] adjusted within the above range, in addition to the coatability of the composition, the wafer edge removability and the hump inhibiting property during the EBR step of a resist underlayer film formed of the composition can be improved.

The upper limit of the Mw/Mn of the polymer [B] is preferably 5, more preferably 3, and still more preferably 2.5. The lower limit of the Mw/Mn is usually 1, and preferably 1.2.

The lower limit of the content of the polymer [B] in the composition is preferably 0.00001 parts by mass, more preferably 0.00005 parts by mass, still more preferably 0.0001 parts by mass, and particularly preferably 0.001 parts by mass per 10 parts by mass of the compound [A]. The upper limit of the content is preferably 2 parts by mass, more preferably 1.5 parts by mass, still more preferably 1 part by mass, and particularly preferably 0.8 parts by mass. Owing to that the content of the polymer [B] is within the above range, not only the coatability of the composition but also the wafer edge removability and the hump inhibiting property during the EBR step of a resist underlayer film formed of the composition can be improved.

### Method for synthesizing polymer [B]

The polymer [B] can be synthesized, for example, by polymerizing, by a known method, a monomer to afford the structural unit (I), a monomer to afford the structural unit (II), and if necessary, a monomer to afford another structural unit each in a use amount leading to a prescribed content ratio.

### Solvent [C]

The solvent [C] is not particularly limited as long as it is a solvent capable of dissolving or dispersing at least the compound [A], the polymer [B], other optional components, and the like. The composition may contain one or two or more of the solvent [C].

Examples of the solvent [C] include organic solvents. Examples of the organic solvent include alcohol-based solvents, ketone-based solvents, ether-based solvents, ester-based solvents, and nitrogen-containing solvents.

Examples of the alcohol-based solvents include monoalcohol-based solvents such as methanol, ethanol, n-propanol, isopropanol, and 1-butanol, and polyhydric alcohol-based solvents such as ethylene glycol, 1, 2-propylene glycol, triethylene glycol, and tripropylene glycol.

Examples of the ketone-based solvents include chain ketone-based solvents such as methyl ethyl ketone, methyl isobutyl ketone, and 2-heptanone; and cyclic ketone-based solvents such as cyclohexanone.

Examples of the ether-based solvents include chain ether-based solvents such as n-butyl ether; polyhydric alcohol ether-based solvents such as cyclic ether-based solvents such as tetrahydrofuran and 1,4-dioxane; and polyhydric alcohol partial ether-based solvents such as propylene glycol monoethyl ether, tripropylene glycol monomethyl ether, and tetraethylene glycol monomethyl ether.

Examples of the ester-based solvents include carbonate-based solvents such as diethyl carbonate; acetic acid monoacetate ester-based solvents such as methyl acetate, ethyl acetate, and butyl acetate; lactone-based solvents such as γ-butyrolactone; polyhydric alcohol partial ether carboxylate-based solvents such as diethylene glycol monomethyl ether acetate and propylene glycol monomethyl ether acetate; and lactic acid ester-based solvents such as methyl lactate and ethyl lactate.

Examples of the nitrogen-containing solvents include chain nitrogen-containing solvents such as N, N-dimethylacetamide, and cyclic nitrogen-containing solvents such as N-methylpyrrolidone.

Additional examples include aromatic hydrocarbon-based solvents such as toluene, xylene, and mesitylene.

As the solvent [C], an ether-based solvent and/or an ester-based solvent is preferable, a polyhydric alcohol partial ether-based solvent and/or a polyhydric alcohol partial ether carboxylate-based solvent is more preferable, and propylene glycol monoethyl ether and/or propylene glycol monomethyl ether acetate is still more preferable.

The lower limit of the content of the solvent [C] accounting for in the total amount of the compound [A] and the solvent [C] is more preferably 50 mass%, preferably 60 mass %, and more preferably 70 mass %. The upper limit of the content is preferably 99% by mass, more preferably 95% by mass, and still more preferably 90% by mass. Owing to that the content of the solvent [C] is adjusted within the above range, the preparation of the composition can be facilitated, and the coatability can be improved.

### Other Optional Components

The composition may contain, for example, an acid generating agent, a macromolecular additive, a polymerization inhibitor, a surfactant, etc. as components other than those described above.

When the composition contains other optional components, the content of the other optional components in the composition can be appropriately determined according to the type, function, and so on of the other optional components to be used.

The acid generating agent is a compound that generates an acid by radiation irradiation and/or heating. The composition may contain one or two or more of the acid generating agent.

Examples of the acid generating agent include an onium salt compound and an N-sulfonyloxyimide compound.

When the composition contains a macromolecular additive, the composition can further enhance the coatability to a substrate and an organic underlayer film and the continuity of a film. The composition may contain one or two or more of the macromolecular additive.

Examples of the macromolecular additive include (poly) oxyalkylene-based macromolecular compounds, fluorine-containing macromolecular compounds, and non-fluorine-containing macromolecular compounds.

Examples of the (poly) oxyalkylene-based macromolecular compounds include: polyoxyalkylenes such as a (poly) oxyethylene-(poly) oxypropylene adduct; (poly) oxyalkyl ethers such as diethylene glycol heptyl ether, polyoxyethylene oleyl ether, polyoxypropylene butyl ether, polyoxyethylene polyoxypropylene-2-ethyl hexyl ether, and an adduct of oxyethylene-oxypropylene to a higher alcohol having 12 to 14 carbon atoms; (poly) oxyalkylene (alkyl) aryl ethers such as polyoxypropylene phenyl ether and polyoxyethylene nonyl phenyl ether; acetylene ethers obtained by addition polymerization of acetylene alcohol and an alkylene oxide, such as 2, 4, 7,9-tetramethyl-5-decyne-4, 7-diol, 2, 5-dimethyl-3-hexyne-2, 5-diol, and 3-methyl-1-butyn-3-ol; (poly) oxyalkylene fatty acid esters such as diethylene glycol oleic acid ester, diethylene glycol lauric acid ester, and ethylene glycol distearic acid ester; (poly) oxyalkylene sorbitan fatty acid esters such as polyoxyethylene sorbitan monolauric acid ester and polyoxyethylene sorbitan trioleic acid ester; (poly) oxyalkylene alkyl (aryl) ether sulfuric acid ester salts such as polyoxypropylene methyl ether sodium sulfate and polyoxyethylene dodecyl phenol ether sodium sulfate; (poly) oxyalkylene alkyl phosphoric acid esters such as (poly) oxyethylene stearyl phosphoric acid ester; and (poly) oxyalkylene alkyl amines such as polyoxyethylene lauryl amine.

Examples of the fluorine-containing macromolecular compounds include compounds disclosed in JP-A-2011-89090. Examples of the fluorine-containing macromolecular compounds include compounds containing a repeating unit derived from a (meth) arylate compound having a fluorine atom and a repeating unit derived from a (meth) acrylate compound having two or more (preferably five or more) alkyleneoxy groups (preferably an ethyleneoxy group, a propyleneoxy group).

Examples of the non-fluorine-containing macromolecular compounds include compounds containing one kind or two or more kinds of repeating units derived from a (meth) acrylate monomer such as a linear or branched alkyl (meth) acrylate such as lauryl (meth) acrylate, 2-ethylhexyl (meth) acrylate, n-butyl (meth) acrylate, t-butyl (meth) acrylate, isooctyl (meth) acrylate, isostearyl (meth) acrylate, or isononyl (meth) acrylate, an alkoxyethyl (meth) acrylate such as methoxyethyl (meth) acrylate, an alkylene glycol di (meth) acrylate such as ethylene glycol di(meth) acrylate or 1,3-butylene glycol di(meth) acrylate, a hydroxyalkyl (meth) acrylate such as 2-hydroxyethyl (meth) acrylate, 2-hydroxypropyl (meth) acrylate, 2-hydroxybutyl (meth) acrylate, or 4-hydroxybutyl (meth) acrylate, dicyclopentenyloxyethyl (meth) acrylate, or nonylphenoxy polyethylene glycol (having a —(CH₂CH₂O)ₙ— structure, n=1 to 17) (meth) acrylate.

When the composition contains a polymerization inhibitor, the storage stability of the composition can be enhanced. The composition may contain one or two or more of the polymerization inhibitor.

Examples of the polymerization inhibitor include hydroquinone compounds such as 4-methoxyphenol and 2,5-di-tert-butylhydroquinone, and nitroso compounds such as N-nitrosophenylhydroxylamine and aluminum salts thereof.

When the composition contains a surfactant, the coatability to a substrate or an organic underlayer film and the continuity of a film can be further enhanced. The composition may contain one or two or more of the surfactant.

Examples of a commercially-available product of the surfactant include “Newcol 2320”, “Newcol 714-F”, “Newcol 723”, “Newcol 2307”, and “Newcol 2303” (which are all manufactured by NIPPON NYUKAZAI CO., LTD.), “Pionin D-1107-S”, “Pionin D-1007”, “Pionin D-1106-DIR”, “Newkalgen TG310”, “Pionin D-6105-W”, “Pionin D-6112”, and “Pionin D-6512” (which are all manufactured by TAKEMOTO OIL & FAT Co., Ltd.), “SURFYNOL 420” “SURFYNOL 440”, “SURFYNOL 465”, and “SURFYNOL 2502” (which are all manufactured by Air Products and Chemicals, Inc.), “MEGAFACE F171”, “MEGAFACE F172”, “MEGAFACE F173”, “MEGAFACE F176”, “MEGAFACE F177”, “MEGAFACE F141”, “MEGAFACE F142”, “MEGAFACE F143”, “MEGAFACE F144”, “MEGAFACE R30”, “MEGAFACE F437”, “MEGAFACE F475”, “MEGAFACE F479”, “MEGAFACE F482”, “MEGAFACE F562”, “MEGAFACE F563”, “MEGAFACE F780”, “MEGAFACE R-40”, “MEGAFACE DS-21”, “MEGAFACE RS-56”, “MEGAFACE RS-90”, and “MEGAFACE RS-72-K” (which are all manufactured by DIC Corporation) , “Fluorad FC430” and “Fluorad FC431” (which are all manufactured by Sumitomo 3M Limited) , “AsahiGuard AG710”, “Surflon S-382”, “Surflon SC-101”, “Surflon SC-102”, “Surflon SC-103”, “Surflon SC-104”, “Surflon SC-105”, and “Surflon SC-106 (which are all manufactured by AGC Inc.), and “FTX-218” and “NBX-15” (manufactured by NEOS Co., Ltd.).

### Method for Preparing Composition for Forming Resist Underlayer Film

The composition for forming a resist underlayer film can be prepared by mixing the compound [A], the polymer [B], the solvent [C] and, as necessary, an optional component in a prescribed ratio and preferably filtering the resulting mixture through a membrane filter having a pore size of 0.5 μm or less, or the like.

### Applying Step

In the applying step, the composition for forming a resist underlayer film formation is applied directly or indirectly to a substrate. The method of the application of the composition for forming a resist underlayer film is not particularly limited, and the application can be performed by an appropriate method such as spin coating, cast coating, or roll coating. As a result, a coating film is formed, and volatilization of the solvent [C] or the like occurs, so that a resist underlayer film is formed.

Examples of the substrate include metal or metalloid substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

The lower limit of the average thickness of the resist underlayer film to be formed is preferably 3 nm, more preferably 5 nm, and still more preferably 10 nm. The upper limit of the average thickness is preferably 500 nm, more preferably 200 nm, and even more preferably 50 nm. The average thickness is measured as described in Examples.

The method for manufacturing a semiconductor substrate preferably further includes heating a coating film formed in the applying step (hereinafter also referred to as a “heating step”). The formation of the resist underlayer film is promoted by heating the coating film. More specifically, volatilization or the like of the solvent [C] is promoted by heating the coating film.

The heating of the coating film is usually performed in the atmosphere but may be performed in a nitrogen atmosphere. The lower limit of a heating temperature is preferably 150° C., and more preferably 200° C. The upper limit of the temperature is preferably 600° C., more preferably 400° C. The lower limit of a heating time is preferably 15 seconds, more preferably 30 seconds. The upper limit of the time is preferably 1,200 seconds, and more preferably 600 seconds.

### Organic Underlayer Film Forming Step

In this step, before the resist pattern forming step, an organic underlayer film is formed directly or indirectly on the substrate having the resist underlayer film formed through the applying step.

The organic underlayer film can be formed by applying a composition for forming an organic underlayer film. One example of a method for forming an organic underlayer film by coating with a composition for forming an organic underlayer film is a method in which the substrate having a resist underlayer film is directly or indirectly coated with a composition for forming an organic underlayer film, and a formed coating film is cured by heating or lithographic exposure. As the composition for forming an organic underlayer film, for example, “HM8006” manufactured by JSR Corporation can be used. Various conditions for heating or exposure can be appropriately determined according to the type of the composition for forming an organic underlayer film to be used.

### Silicon-Containing Film Forming Step

In this step, before the resist pattern forming step, a silicon-containing film is formed directly or indirectly on the substrate having the resist underlayer film formed through the applying step.

One example of a case where a silicon-containing film is indirectly formed on the substrate having a resist underlayer film is a case where a surface modification film for the resist underlayer film is formed on the resist underlayer film.

The silicon-containing film can be formed by, for example, coating with a composition for forming a silicon-containing film, chemical vapor deposition (CVD), or atomic layer deposition (ALD). Examples of a method for forming a silicon-containing film by coating a composition for forming a silicon-containing film include a method including curing, by lithographic exposure and/or heating, a coating film formed by applying the composition for forming a silicon-containing film directly or indirectly to the resist underlayer film. As a commercially-available product of the composition for forming a silicon-containing film, for example, “NFC SOG01”, “NFC SOG04”, “NFC SOG080” (which are all manufactured by JSR Corporation), or the like can be used. By chemical vapor deposition (CVD) or atomic layer deposition (ALD), a silicon oxide film, a silicon nitride film, a silicon oxynitride film, or an amorphous silicon film can be formed.

### Resist Pattern Forming Step

In this step, a resist pattern is formed directly or indirectly on the resist underlayer film. Examples of a method for performing this step include a method using a resist composition, a method using nanoimprinting, and a method using a self-assembly composition. One example of a case where a resist pattern is indirectly formed on the resist underlayer film is a case where, when the method for manufacturing a semiconductor substrate includes the silicon-containing film forming step, a resist pattern is formed on the silicon-containing film.

Specifically, the method using a resist composition is performed by applying a resist composition in such a manner that a resist film to be formed has a predetermined thickness and then volatilizing a solvent in a coating film by pre-baking to form a resist film.

Examples of the resist composition include a positive or negative chemically amplified resist composition containing a radiation sensitive acid generating agent, a positive resist composition containing an alkali-soluble resin and a quinonediazide-based photosensitizer, and a negative resist composition containing an alkali-soluble resin and a crosslinking agent. It should be noted that in this step, a commercially-available resist composition may directly be used.

Then, the formed resist film is subjected to exposure to light by selective irradiation with radiation. Radiation used for lithographic exposure can appropriately be selected depending on the type of radiation sensitive acid generating agent used in the resist composition, and examples thereof include electromagnetic rays such as visible rays, ultraviolet rays, far-ultraviolet, X rays, and γ rays and corpuscular rays such as electron rays, molecular rays, and ion beams. Among them, far-ultraviolet is preferred, KrF excimer laser light (248 nm), ArF excimer laser light (193 nm), F₂ excimer laser light (wavelength: 157 nm), Kr₂ excimer laser light (wavelength: 147 nm), ArKr excimer laser light (wavelength: 134 nm), or extreme ultraviolet (wavelength: 13.5 nm, hereinafter also referred to as “EUV”) is more preferred, and KrF excimer laser light, ArF excimer laser light, or EUV is even more preferred.

After the exposure to light, post-baking may be performed to improve resolution, pattern profile, developability, etc. The temperature and time of the post-baking may be appropriately determined according to the type or the like of the resist composition to be used.

Then, the exposed resist film is developed with a developer to form a resist pattern. This development may be either alkaline development or organic solvent development. Examples of the developer for alkaline development include basic aqueous solutions of ammonia, triethanolamine, tetramethylammonium hydroxide (TMAH), and tetraethylammonium hydroxide. To these basic aqueous solutions, for example, a water-soluble organic solvent such as an alcohol, e.g., methanol or ethanol, or a surfactant may be added in an appropriate amount. Examples of the developer for organic solvent development include various organic solvents mentioned above as examples of the solvent [C] contained in the composition.

After the development with a developer, a prescribed resist pattern is formed through washing and drying.

### Etching Step

In this step, a pattern is formed to the resist underlayer film by etching using the resist pattern as a mask. The number of times of etching may be once or twice or more, that is, etching may sequentially be performed using a pattern obtained by etching as a mask. However, from the viewpoint of obtaining a pattern having a further superior shape, etching is preferably performed twice or more. When performed a plurality of times, etching is performed to the silicon-containing film, the organic underlayer film, the resist underlayer film, and the substrate sequentially in order. Examples of an etching method include dry etching and wet etching. Among them, dry etching is preferred from the viewpoint of achieving a further superior pattern shape of the substrate. The dry etching uses, for example, gas plasma such as oxygen plasma. As a result of the etching, a semiconductor substrate having a prescribed pattern is obtained.

The dry etching can be performed using, for example, a known dry etching device. An etching gas used for the dry etching can appropriately be selected depending on, for example, a mask pattern or the elemental composition of a film to be etched, and examples thereof include a fluorine-based gas such as CHF₃,CF₄, C₂F₆, C₃F₈, or SF₆, a chlorine-based gas such as Cl2 or BC13, an oxygen-based gas such as O₂, O₃, or H₂O, a reductive gas such as He, CO, CO₂, CH₄, C₂H₂, C₂H₄, C₂H₆, C₃H₄, C₃H₆, C₃H₈, HF, HI, HBr, HCl, NO, NH₃, or BCl₃, and an inert gas such as He, N₂, or Ar. These gases can also be used in admixture. When the substrate is etched using the pattern of the resist underlayer film as a mask, a fluorine-based gas is usually used.

### Method for Forming Resist Underlayer Film

The method for forming a resist underlayer film includes a step of applying a composition for forming a resist underlayer film directly or indirectly to a substrate. As the composition for forming a resist underlayer film, the composition for forming a resist underlayer film to be used in the above-described method for manufacturing a semiconductor substrate can be suitably employed. As the applying step, the applying step of the above-described method for manufacturing a semiconductor substrate can be suitably employed.

### EXAMPLES

Hereinafter, Examples are described. The following Examples merely illustrate typical Examples of the present invention, and the Examples should not be construed to narrow the scope of the present invention.

A concentration of the components other than the solvent in the mixture containing the compound [A] in the present example, a weight-average molecular weight (Mw) of the hydrolysis-condensate in the mixture containing the compound [A], a weight-average molecular weight (Mw) of the polymer [B], and an average thickness of the film were measured by the following methods.

### Concentration of Components Other Than Solvent in Mixture Containing Compound [A]

By firing 0.5 g of a mixture containing the compound [A] at 250° ° C.for 30 minutes, measuring a mass of the residue thus obtained, and dividing the mass of the residue by the mass of the solution containing the compound [A], the concentration (% by mass) of the components other than the solvent in the mixture containing the compound [A] was calculated.

### Weight-Average Molecular Weight (Mw) of Hydrolysis-Condensate in Mixture Containing Compound [A]

The weight-average molecular weight was measured by gel permeation chromatography (detector: differential refractometer) with monodisperse polystyrene standards using GPC columns (“AWM-H”×2, “AW-H”×1, and “AW2500”×2) manufactured by Tosoh Corporation under the analysis conditions specified by flow rate: 0.3 mL/min, elution solvent: mixture of N, N-dimethylacetamide with LiBr (30 mM) and citric acid (30 mM), and column temperature: 40° C.

### Weight-Average Molecular Weight (Mw) of Polymer [B]

The Mw of a polymer was measured by gel permeation chromatography (detector: differential refractometer) with monodisperse polystyrene standards using GPC columns (“G2000HXL”×2, “G3000HXL”×1, and “G4000HXL”×1) manufactured by Tosoh Corporation under the analysis conditions specified by flow rate: 1.0 mL/min; elution solvent: tetrahydrofuran; and column temperature: 40° C.

### Average Thickness of Resist Underlayer Film

The average thickness of a resist underlayer film was determined by measuring film thicknesses at arbitrary nine points at intervals of 5 cm including the center of the resist underlayer film formed on a silicon wafer, using a spectroscopic ellipsometer (“M2000D” available from J.A. WOOLLAM Co.) and calculating the average value of the film thicknesses.

### Synthesis of Compound [A]

The compound [m], the compound [x], the solvent [d], and the solvent [C] used for the synthesis of the compound [A] are listed below. In the following synthesis examples, unless otherwise specified, “parts by mass” means a value taken when the mass of the compound [m] used is 100 parts by mass. In addition, the “molar ratio” means a value taken when the amount of the compound [m] used is 1. The concentrations (% by mass) of components other than the solvent in the mixture containing the compound [A] are also shown in Table 1.

The following compounds were used as the compound [m].
m-1: Tetra-n-propoxyzirconium (IV)
m-2: Tetra-n-butoxyzirconium (IV)
m-3: Tetra-n-propoxyhafnium (IV)
m-4: Tetraisopropoxytitanium (IV)
m-5: Pentaethoxytantalum (V)

The following compounds were used as the compound [x].
x-1: Propionic acid
x-2: Butyric acid
x-3: Isobutyric acid
x-4: Methacrylic acid
x-5: 2-Ethylhexanoic acid
x-6: Acetylacetone
x-7: Diethanolamine

The following compounds were used as the solvent [d].
d-1: n-Propanol
d-2: Ethanol
d-3: 1-Butanol
d-4: Isopropanol

As the solvent [C], the following compounds were used.
C-1: Propylene glycol monomethyl ether acetate
C-2: Propylene glycol monoethyl ether

### Synthesis Example 1-1 (Synthesis of Compound [A] (A-1))

The compound (m-1) and the solvent (d-1) (40 parts by mass) were charged into a reaction vessel under a nitrogen atmosphere. In the reaction vessel, the compound (x-1) (molar ratio: 5) was added dropwise over 20 minutes with stirring at 50° C. The reaction was then carried out at 80ºC for 3 hours. After the completion of the reaction, the inside of the reaction vessel was cooled to 30° C. or lower. The precipitate obtained via the cooling was collected by filtration, washed with n-hexane (100 parts by mass), and then vacuum-dried, affording compound (A-1).

### Synthesis Example 1-2 (Synthesis of Compound [A] (A-2))

The compound (m-1) and the solvent (d-1) (200 parts by mass) were charged into a reaction vessel under a nitrogen atmosphere. In the reaction vessel, the compound (x-2) (molar ratio: 5) was added dropwise over 20 minutes with stirring at 50° C. The reaction was then carried out at 80° C. for 3 hours. After the completion of the reaction, the inside of the reaction vessel was cooled to 30° C. or lower. After 900 parts by mass of the solvent (C-1) was added to the cooled reaction solution, the solvent (d-1), the alcohol generated via the reaction, and the excess solvent (C-1) were removed using an evaporator, affording a mixture containing compound (A-2). The concentration of the components other than the solvent in the mixture containing the compound [A] (A-2) was 14% by mass.

### Synthesis Examples 1-10 and 1-14 (Synthesis of Compounds [A] (A-10) and (A-14))

Compounds [A] (A-10) and (A-14) were obtained in the same manner as in Synthesis Example 1-1 except that the compound [m], the compound [x] and the solvent [d] of the type and use amount given in the following Table 1 were used.

### Synthesis Examples 1-3 to 1-9 and 1-11 to 1-13 (Synthesis of Compounds [A] (A-3) to (A-9) and (A-11) to (A-13))

Mixtures containing compounds [A] (A-3) to (A-9) and (A-11) to (A-13) were obtained in the same manner as in Synthesis Example 1-2 except that the compound [m], the compound [x], the solvent [d], and the solvent [C] of the type and use amount given in the following Table 1 were used.

### Synthesis Example 1-15 (Synthesis of Compound [A] (A-15))

The compound (m-4) was charged into a reaction vessel under a nitrogen atmosphere. In the reaction vessel, the compound (x-6) (molar ratio: 2) was added dropwise over 30 minutes with stirring at room temperature (25° C. to 30° C.) . The reaction was then carried out at 60° C. for 2 hours. After the completion of the reaction, the inside of the reaction vessel was cooled to 30° C. or lower. The cooled reaction solution was diluted with the solvent (d-4) (900 parts by mass) . In the reaction vessel, water (molar ratio: 2) was added dropwise over 10 minutes with stirring at room temperature (25° C. to 30° C.) . A hydrolysis-condensation reaction was then carried out at 60° C. for 2 hours. After the completion of the hydrolysis-condensation reaction, the inside of the reaction vessel was cooled to 30° C. or lower. After 1,000 parts by mass of the solvent (C-2) was added to the cooled reaction solution, water, isopropanol, the alcohol generated via the reaction, and the excess solvent (C-2) were removed using an evaporator, affording a mixture containing compound (A-15). The concentration of the components other than the solvent in the mixture containing the compound [A] (A-15) was 13% by mass. The Mw of the compound (A-15) was 2,800.

### Synthesis Example 1-16 (Synthesis of Compound [A] (A-16))

A mixture containing compound [A] (A-16) was obtained in the same manner as in Synthesis Example 1-15 except that the compound [m], the compound [x], the solvent [d], and the solvent [C] of the type and use amount given in the following Table 1 were used. The Mw of the compound (A-16) was 1,600.

TABLE 1

| | | | | | | | | Concentration of |
|---|---|---|---|---|---|---|---|---|
| | | | | | | | | components other |
| | | | | | | | | than solvent in |
| | | | | | | | | mixture containing |
| | | Compound [m] | | Compound [x] | | Solvent [d] | Solvent [C] | compound [A] |
| | Compound [A] | Type | mol % | Type | mol % | Type | Type | (% by mass) |
| Synthesis Example 1-1 | A-1 | m-1 | 1 | x-1 | 5 | d-1 | — | 100 |
| Synthesis Example 1-2 | A-2 | m-1 | 1 | x-2 | 5 | d-1 | C-1 | 14 |
| Synthesis Example 1-3 | A-3 | m-1 | 1 | x-3 | 5 | d-1 | C-1 | 14 |
| Synthesis Example 1-4 | A-4 | m-1 | 1 | x-4 | 1 | d-1 | C-1 | 13 |
| Synthesis Example 1-5 | A-5 | m-1 | 1 | x-4 | 2 | d-1 | C-1 | 13 |
| Synthesis Example 1-6 | A-6 | m-1 | 1 | x-4 | 3 | d-1 | C-1 | 13 |
| Synthesis Example 1-7 | A-7 | m-1 | 1 | x-4 | 5 | d-1 | C-1 | 13 |
| Synthesis Example 1-8 | A-8 | m-1 | 1 | x-5 | 5 | d-1 | C-1 | 14 |
| Synthesis Example 1-9 | A-9 | m-2 | 1 | x-4 | 5 | d-3 | C-1 | 13 |
| Synthesis Example 1-10 | A-10 | m-3 | 1 | x-4 | 5 | d-1 | — | 100 |
| Synthesis Example 1-11 | A-11 | m-4 | 1 | x-3 | 5 | d-4 | C-1 | 13 |
| Synthesis Example 1-12 | A-12 | m-5 | 1 | x-3 | 6 | d-2 | C-1 | 13 |
| Synthesis Example 1-13 | A-13 | m-2 | 1 | x-6 | 1 | d-3 | C-2 | 14 |
| Synthesis Example 1-14 | A-14 | m-2 | 1 | x-6 | 4 | d-3 | — | 100 |
| Synthesis Example 1-15 | A-15 | m-4 | 1 | x-6 | 2 | d-4 | C-2 | 13 |
| Synthesis Example 1-16 | A-16 | m-4 | 1 | x-7 | 2 | d-4 | C-1 | 20 |

### Synthesis of Polymer [B]

As the polymer [B], polymers represented by the following formulas (B-1) to (B-10) and (b-1) (hereinafter also referred to as “polymers (B-1) to (B-10) and (b-1)”) were synthesized by the following procedures.

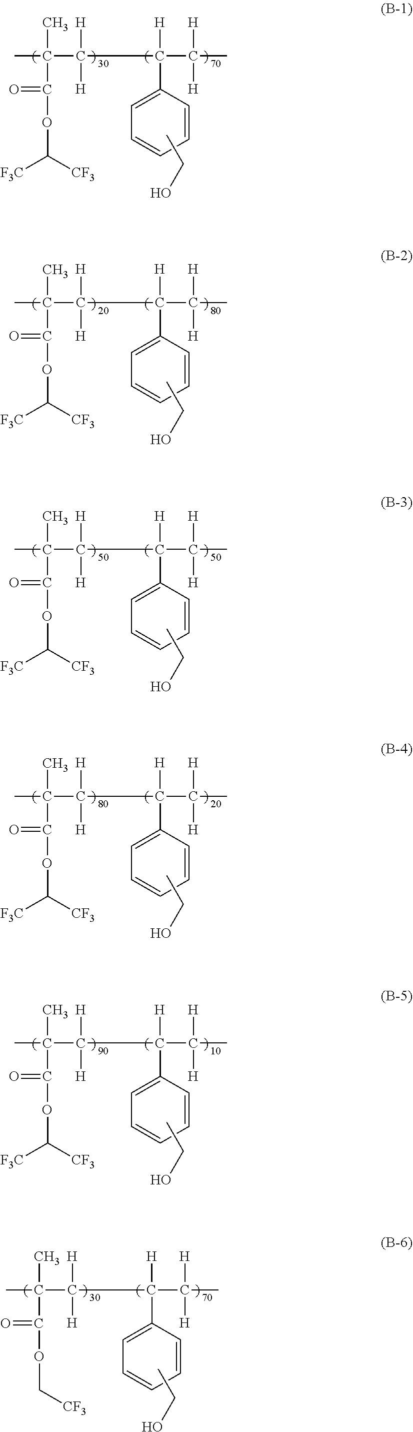

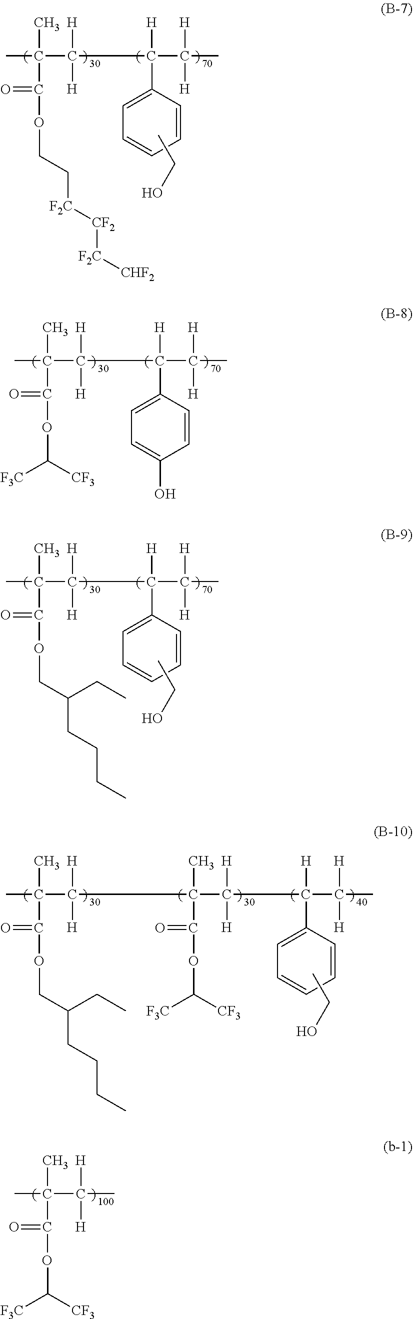

In the above formulas (B-1) to (B-10) and (b-1), the number attached to each structural unit indicates the content ratio (mol %) of the structural unit.

### Synthesis Example 2-1 (Synthesis of Polymer (B-1))

1, 1, 1, 3, 3, 3-Hexafluoroisopropyl methacrylate (43.0 g) and vinylbenzyl alcohol (57.0 g) were dissolved in 130 g of methyl isobutyl ketone, and 19.6 g of dimethyl 2,2′-azobis (2-methylpropionate) was added to prepare a monomer solution. In a nitrogen atmosphere, 70 g of methyl isobutyl ketone was placed in a reaction vessel and heated to 80° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether acetate, and methyl isobutyl ketone was removed by concentration under reduced pressure, affording a propylene glycol monomethyl ether acetate solution of polymer (B-1). The Mw of the polymer (B-1) was 4,200.

### Synthesis Examples 2-2 to 2-11 (Synthesis of Polymers (B-2) to (B-10) and (b-1))

Propylene glycol monomethyl ether acetate solutions of the polymers (B-2) to (B-10) and (b-1) were obtained in the same manner as in Synthesis Example 2-1 except that monomers capable of affording the structural units in the content ratios (mol %) shown in the formulas (B-2) to (B-10) and (b-1) were used. The Mw of the polymer (B-2) was 3,800, the Mw of the polymer (B-3) was 4,000, the Mw of the polymer (B-4) was 4,300, the Mw of the polymer (B-5) was 4,500, the Mw of the polymer (B-6) was 4,100, the Mw of the polymer (B-7) was 4,100, the Mw of the polymer (B-8) was 4,200, the Mw of the polymer (B-9) was 4,200, the Mw of the polymer (B-10) was 4,300, and the Mw of the polymer (b-1) was 4,100.

### Preparation of Composition

The compounds [A], the polymers [B], the solvents [C], and other optional components [F] are described below.

The compounds (A-1) to (A-16) synthesized above were used as the compound [A].

The polymers (B-1) to (B-10) and (b-1) synthesized above were used as the polymer [B].

In addition to (C-1) and (C-2) used for the synthesis of the compound [A], the following compounds were used as the solvent [C].
C-3: Cyclohexanone
C-4: 2-Heptanone
C-5: Mesitylene
C-6: Butyl acetate

The following compounds were used as other optional component [F].
F-1: 4-Methoxyphenol
F-2: Surfactant (“NBX-15” manufactured by NEOS Co., Ltd.)
F-3: Surfactant (“F563” manufactured by DIC Corporation)

### Example 1-1 Preparation of Composition (J-1)

As shown in the following Table 2, 0.05 parts by mass of the polymer [B] (B-1) and 90 parts by mass of (C-3) as the solvent [C] were mixed per 10 parts by mass of the compound [A] (A-1). The resulting solution was filtered through a polytetrafluoroethylene (PTFE) filter having a pore size of 0.2 μm to prepare composition (J-1). “-” for polymer [B] and other optional components [F] in the following Table 2 indicates that the polymer [B] and the other optional components [F] were not used. The same applies hereinafter.

### Example 1-2 Preparation of Composition (J-2)

As shown in the following Table 2, a mixture containing the compound [A] (A-2) and (C-1) as the solvent [C] were mixed such that the amount of the polymer [B] (B-1) was 0.05 parts by mass and the amount of the solvent [C] (including the solvent [C] contained in the mixture containing the compound [A]) was 90 parts by mass per 10 parts by mass of the components other than the solvent in the compound [A] (A-2). The resulting solution was filtered through a polytetrafluoroethylene (PTFE) filter having a pore size of 0.2 μm to prepare composition (J-2).

### Examples 1-3 to 1-38 Preparation of Compositions (J-3) to (J-38)

Compositions (J-3) to (J-38) were prepared in the same manner as in Example 1-1 or Example 1-2 except that the type and content of each component were set as shown in the following Table 2.

### Comparative Examples 1-1 to 1-4 Preparation of Compositions (J-1) to (J-4)

Compositions (j-1) to (j-4) were prepared in the same manner as in Example 1-2 except that the type and content of each component were set as shown in the following Table 2.

TABLE 2

| | | Compound [A] or | | | | | | | |
|---|---|---|---|---|---|---|---|---|---|
| | | components other than | | | | | | | |
| | | solvent in mixture | | | | | | Other optional | |
| | | containing compound [A] | | Polymer [B] | | Solvent [C] | | components [F] | |
| | | | Content | | Content | | Content | | Content |
| | | | (parts by | | (parts by | | (parts by | | (parts by |
| | Composition (J) | Type | mass) | Type | mass) | Type | mass) | Type | mass) |
| Example 1-1 | J-1 | A-1 | 10 | B-1 | 0.05 | C-3 | 90 | — | — |
| Example 1-2 | J-2 | A-2 | 10 | B-1 | 0.05 | C-1 | 90 | — | — |
| Example 1-3 | J-3 | A-3 | 10 | B-1 | 0.05 | C-1 | 90 | — | — |
| Example 1-4 | J-4 | A-4 | 10 | B-1 | 0.05 | C-1 | 90 | F-1 | 0.005 |
| Example 1-5 | J-5 | A-5 | 10 | B-1 | 0.05 | C-1 | 90 | F-1 | 0.005 |
| Example 1-6 | J-6 | A-6 | 10 | B-1 | 0.05 | C-1 | 90 | F-1 | 0.005 |
| Example 1-7 | J-7 | A-7 | 10 | B-1 | 0.05 | C-1 | 90 | F-1 | 0.005 |
| Example 1-8 | J-8 | A-7 | 10 | B-2 | 0.05 | C-1 | 90 | F-1 | 0.005 |
| Example 1-9 | J-9 | A-7 | 10 | B-3 | 0.05 | C-1 | 90 | F-1 | 0.005 |
| Example 1-10 | J-10 | A-7 | 10 | B-4 | 0.05 | C-1 | 90 | F-1 | 0.005 |
| Example 1-11 | J-11 | A-7 | 10 | B-5 | 0.05 | C-1 | 90 | F-1 | 0.005 |
| Example 1-12 | J-12 | A-7 | 10 | B-6 | 0.05 | C-1 | 90 | F-1 | 0.005 |
| Example 1-13 | J-13 | A-7 | 10 | B-7 | 0.05 | C-1 | 90 | F-1 | 0.005 |
| Example 1-14 | J-14 | A-7 | 10 | B-8 | 0.05 | C-1 | 90 | F-1 | 0.005 |
| Example 1-15 | J-15 | A-7 | 10 | B-9 | 0.05 | C-1 | 90 | F-1 | 0.005 |
| Example 1-16 | J-16 | A-7 | 10 | B-10 | 0.05 | C-1 | 90 | F-1 | 0.005 |
| Example 1-17 | J-17 | A-8 | 10 | B-1 | 0.05 | C-1 | 90 | — | — |
| Example 1-18 | J-18 | A-9 | 10 | B-1 | 0.05 | C-1 | 90 | F-1 | 0.005 |
| Example 1-19 | J-19 | A-9 | 10 | B-1 | 0.1 | C-1 | 90 | F-1 | 0.005 |
| Example 1-20 | J-20 | A-9 | 10 | B-1 | 0.3 | C-1 | 90 | F-1 | 0.005 |
| Example 1-21 | J-21 | A-9 | 10 | B-1 | 0.5 | C-1 | 90 | F-1 | 0.005 |
| Example 1-22 | J-22 | A-9 | 10 | B-1 | 0.7 | C-1 | 90 | F-1 | 0.005 |
| Example 1-23 | J-23 | A-9 | 10 | B-1 | 1 | C-1 | 90 | F-1 | 0.005 |
| Example 1-24 | J-24 | A-9 | 10 | B-1 | 0.03 | C-1 | 90 | F-1 | 0.005 |
| Example 1-25 | J-25 | A-9 | 10 | B-1 | 0.01 | C-1 | 90 | F-1 | 0.005 |
| Example 1-26 | J-26 | A-9 | 10 | B-1 | 0.005 | C-1 | 90 | F-1 | 0.005 |
| Example 1-27 | J-27 | A-9 | 10 | B-1 | 0.003 | C-1 | 90 | F-1 | 0.005 |
| Example 1-28 | J-28 | A-9 | 10 | B-1 | 0.001 | C-1 | 90 | F-1 | 0.005 |
| Example 1-29 | J-29 | A-9 | 10 | B-1 | 0.0001 | C-1 | 90 | F-1 | 0.005 |
| Example 1-30 | J-30 | A-9 | 10 | B-1 | 0.05 | C-1/C-4 | 72/18 | F-1 | 0.005 |
| Example 1-31 | J-31 | A-9 | 10 | B-1 | 0.05 | C-1/C-6 | 54/36 | F-1 | 0.005 |
| Example 1-32 | J-32 | A-10 | 10 | B-1 | 0.05 | C-1 | 90 | F-1 | 0.005 |
| Example 1-33 | J-33 | A-11 | 10 | B-1 | 0.05 | C-1 | 90 | — | — |
| Example 1-34 | J-34 | A-12 | 10 | B-1 | 0.05 | C-1 | 90 | — | — |
| Example 1-35 | J-35 | A-13 | 10 | B-1 | 0.05 | C-2 | 90 | — | — |
| Example 1-36 | J-36 | A-14 | 10 | B-1 | 0.05 | C-5 | 90 | — | — |
| Example 1-37 | J-37 | A-15 | 10 | B-1 | 0.05 | C-2 | 90 | — | — |
| Example 1-38 | J-38 | A-16 | 10 | B-1 | 0.05 | C-1 | 90 | — | — |
| Comparative | j-1 | A-9 | 10 | b-1 | 0.05 | C-1 | 90 | F-1 | 0.005 |
| Example 1-1 | | | | | | | | | |
| Comparative | j-2 | A-9 | 10 | — | — | C-1 | 90 | F-1/F-2 | 0.005/0.05 |
| Example 1-2 | | | | | | | | | |
| Comparative | j-3 | A-9 | 10 | — | — | C-1 | 90 | F-1/F-3 | 0.005/0.05 |
| Example 1-3 | | | | | | | | | |
| Comparative | j-4 | A-9 | 10 | — | — | C-1 | 90 | F-1 | 0.005 |
| Example 1-4 | | | | | | | | | |

### Evaluation

Using each of the compositions prepared above, coatability, wafer edge removability, and hump inhibiting property were evaluated according to the following methods. The evaluation results are given in the following Table 3.

### Formation of Substrate with Resist Underlayer Film Subjected to EBR Treatment

A composition immediately after the preparation thereof was applied to a silicon wafer (substrate) by spin coating using a spin coater (“CLEAN TRACK ACT 8” available from Tokyo Electron Ltd.). Then, with rotation at 1500 rpm, while a removing liquid discharge nozzle was moved at a rate of 1 mm per second, a removing liquid (propylene glycol monomethyl ether acetate/propylene glycol monoethyl ether=30/70, mass ratio) was discharged at a discharge rate of 2 ml per second to a position 2 mm away from the outer peripheral edge of the substrate toward the center of the substrate. After the removing liquid was discharged for 10 seconds at a discharge rate of 2 ml per second at the position 2 mm away from the outer peripheral edge of the substrate toward the center of the substrate, the discharge of the removing liquid was stopped, and the substrate was rotated at 1,500 rpm for 30 seconds. Next, this substrate was heated at 450° C. for 60 seconds, affording a substrate with a resist underlayer film having an average thickness of 30 nm.

### Coatability

Regarding the coatability, the substrate with the resist underlayer film was visually observed, and when no circular coating defect was observed, it was evaluated as “A” (good), and when one or more circular coating defects were present, it was evaluated as “B” (poor).

### Wafer Edge Removability

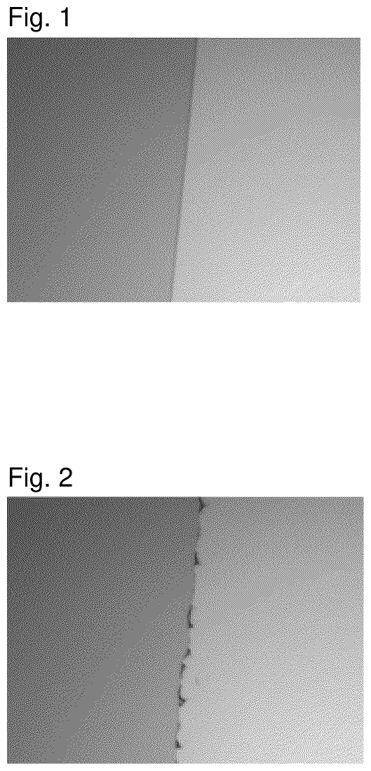

Regarding the wafer edge removability, a wafer peripheral portion extending up to 5 mm from the outer peripheral edge of the substrate with the resist underlayer film toward the center of the substrate was observed with an optical microscope (10 magnifications), and when no removal unevenness was observed, it was evaluated as “A” (good), whereas when removal unevenness was observed, it was evaluated “B” (poor). FIG. 1 is an optical micrograph taken in a case where no removal unevenness was observed in the evaluation of the wafer edge removability, and FIG. 2 is an optical micrograph in a case where removal unevenness was observed in the evaluation of the wafer edge removability.

### Hump Inhibiting Property

Regarding the hump inhibiting property, the height changes at positions up to 10 mm from the outer peripheral edge of the substrate with the resist underlayer film toward the center of the substrate was measured using a stylus profiler (KLA Alpha-Step D-600, stylus pressure: 5 mg). Where the height of a substrate without a resist underlayer film was defined as 0, a substrate with the resist underlayer film having a height of less than 40 nm was evaluated as “A” (good), a height of 40 nm or more and less than 50 nm was evaluated as “B” (slightly good or slightly poor), and a height of 50 nm or more was evaluated as “C” (poor).

TABLE 3

| | | | | Hump |
|---|---|---|---|---|
| | | | Wafer edge | inhibiting |
| | Composition | Coatability | removability | property |
| Example 1-1 | J-1 | A | A | A |
| Example 1-2 | J-2 | A | A | A |
| Example 1-3 | J-3 | A | A | A |
| Example 1-4 | J-4 | A | A | A |
| Example 1-5 | J-5 | A | A | A |
| Example 1-6 | J-6 | A | A | A |
| Example 1-7 | J-7 | A | A | A |
| Example 1-8 | J-8 | A | A | A |
| Example 1-9 | J-9 | A | A | A |
| Example 1-10 | J-10 | A | A | A |
| Example 1-11 | J-11 | A | A | A |
| Example 1-12 | J-12 | A | A | A |
| Example 1-13 | J-13 | A | A | A |
| Example 1-14 | J-14 | A | A | A |
| Example 1-15 | J-15 | A | A | A |
| Example 1-16 | J-16 | A | A | A |
| Example 1-17 | J-17 | A | A | A |
| Example 1-18 | J-18 | A | A | A |
| Example 1-19 | J-19 | A | A | A |
| Example 1-20 | J-20 | A | A | A |
| Example 1-21 | J-21 | A | A | A |
| Example 1-22 | J-22 | A | A | A |
| Example 1-23 | J-23 | A | A | B |
| Example 1-24 | J-24 | A | A | A |
| Example 1-25 | J-25 | A | A | A |
| Example 1-26 | J-26 | A | A | A |
| Example 1-27 | J-27 | A | A | A |
| Example 1-28 | J-28 | A | A | A |
| Example 1-29 | J-29 | A | A | B |
| Example 1-30 | J-30 | A | A | A |
| Example 1-31 | J-31 | A | A | A |
| Example 1-32 | J-32 | A | A | A |
| Example 1-33 | J-33 | A | A | A |
| Example 1-34 | J-34 | A | A | A |
| Example 1-35 | J-35 | A | A | A |
| Example 1-36 | J-36 | A | A | A |
| Example 1-37 | J-37 | A | A | A |
| Example 1-38 | J-38 | A | A | A |
| Comparative | j-1 | B | B | C |
| Example 1-1 | | | | |
| Comparative | j-2 | B | B | C |
| Example 1-2 | | | | |
| Comparative | j-3 | B | B | C |
| Example 1-3 | | | | |
| Comparative | j-4 | A | B | C |
| Example 1-4 | | | | |

As can be seen from the results in Table 3, the compositions of Examples and the resist underlayer films formed from the compositions were superior in coatability, wafer edge removability, and hump inhibiting property to Comparative Examples.

The composition for forming a resist underlayer film of the present disclosure is superior in all of coatability, wafer edge removability during an EBR step, and hump inhibiting property. In the method for manufacturing a semiconductor substrate according to the present disclosure, a resist underlayer film is formed using a composition for forming a resist underlayer film that is superior in both coatability, wafer edge removability during the EBR step, and hump inhibiting property, so that a high-quality semiconductor substrate can be efficiently manufactured. By the method for forming a resist underlayer film of the present disclosure, a desired resist underlayer film can be efficiently formed because a composition for forming a resist underlayer film superior in all of coatability, wafer edge removability during the EBR step, and hump inhibiting property is used. Therefore, these can suitably be used for, for example, manufacturing semiconductor devices expected to be further microfabricated in the future.

Obviously, numerous modifications and variations of the present invention (s) are possible in light of the above teachings. It is therefore to be understood that within the scope of the appended claims, the invention (s) may be practiced otherwise than as specifically described herein.

What is claimed is:

1. A composition comprising:
a metal compound;
a polymer comprising a first structural unit represented by formula (1) and a second structural unit represented by formula (2); and
a solvent, 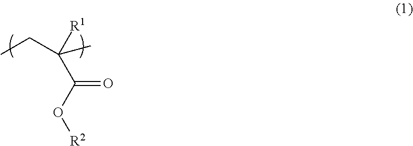
in the formula (1), R¹ is a hydrogen atom or a substituted or unsubstituted monovalent hydrocarbon group having 1 to 20 carbon atoms; and R² is a substituted or unsubstituted monovalent hydrocarbon group having 1 to 20 carbon atoms, 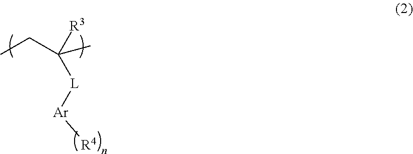
in the formula (2), R³ is a hydrogen atom or a substituted or unsubstituted monovalent hydrocarbon group having 1 to 20 carbon atoms; L is a single bond or a divalent linking group; Ar is a group obtained by removing (n+1) hydrogen atoms from a substituted or unsubstituted aromatic ring having 6 to 20 ring members; R⁴ is a monovalent hydroxyalkyl group having 1 to 10 carbon atoms or a hydroxy group; n is an integer of 0 to 8; and when n is 2 or more, a plurality of R⁴s are the same or different from each other.

2. The composition according to claim 1, wherein a content of the polymer based on 10 parts by mass of the metal compound is 0.00001 parts by mass or more and 2 parts by mass or less.

3. The composition according to claim 1, wherein R² is a substituted or unsubstituted monovalent chain hydrocarbon group having 1 to 20 carbon atoms.

4. The composition according to claim 1, wherein R² is a substituted monovalent chain hydrocarbon group having 1 to 20 carbon atoms, and a part or all of the hydrogen atoms of the chain hydrocarbon group are substituted with fluorine atoms.

5. The composition according to claim 1, wherein in the formula (2), n is an integer of 1 to 8, and at least one R⁴ is a monohydroxyalkyl group.

6. The composition according to claim 5, wherein the monohydroxyalkyl group is a monohydroxymethyl group.

7. The composition according to claim 1, wherein a content ratio of the first structural unit accounting for in all structural units constituting the polymer is 10 mol % or more and 90 mol % or less.

8. The composition according to claim 1, wherein a content ratio of the second structural unit accounting for in all structural units constituting the polymer is 10 mol % or more and 90 mol % or less.

9. The composition according to claim 1, wherein a metal atom contained in the metal compound belongs to Groups 3 to 16 of a periodic table.

10. The composition according to claim 1, wherein a metal atom contained in the metal compound belongs to Group 4 of a periodic table.

11. The composition m according to claim 1, wherein a content ratio of the metal compound accounting for in all components contained in the composition for forming a resist underlayer film is 2% by mass or more and 30% by mass or less.

12. A method for manufacturing a semiconductor substrate, the method comprising:
applying a composition for forming a resist underlayer film directly or indirectly to a substrate to form a resist underlayer film;
forming a resist pattern directly or indirectly on the resist underlayer film; and
forming a pattern on the resist underlayer film by etching using the resist pattern as a mask,
wherein
the composition for forming a resist underlayer film comprises:
a metal compound;
a polymer comprising a first structural unit represented by formula (1) and a second structural unit represented by formula (2); and
a solvent, 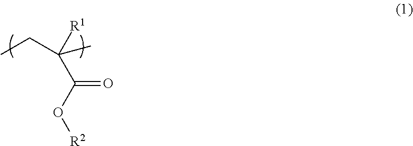
in the formula (1), R¹ is a hydrogen atom or a substituted or unsubstituted monovalent hydrocarbon group having 1 to 20 carbon atoms; and R² is a substituted or unsubstituted monovalent hydrocarbon group having 1 to 20 carbon atoms, 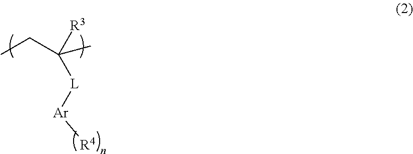
in the formula (2), R³ is a hydrogen atom or a substituted or unsubstituted monovalent hydrocarbon group having 1 to 20 carbon atoms; L is a single bond or a divalent linking group; Ar is a group obtained by removing (n+1) hydrogen atoms from a substituted or unsubstituted aromatic ring having 6 to 20 ring members; R⁴ is a monovalent hydroxyalkyl group having 1 to 10 carbon atoms or a hydroxy group; n is an integer of 0 to 8; and when n is 2 or more, a plurality of R⁴s are the same or different from each other.

13. The method for manufacturing a semiconductor substrate according to claim 12, further comprising, before forming the resist pattern,
forming an organic underlayer film directly or indirectly on the resist underlayer film.

14. The method for manufacturing a semiconductor substrate according to claim 12, further comprising, before forming the resist pattern,
forming a silicon-containing film directly or indirectly on the resist underlayer film.

15. A method for forming a resist underlayer film, the method comprising applying a composition for forming a resist underlayer film directly or indirectly to a substrate,
wherein
the composition for forming a resist underlayer film comprises:
a metal compound;
a polymer comprising a first structural unit represented by formula (1) and a second structural unit represented by formula (2); and
a solvent, 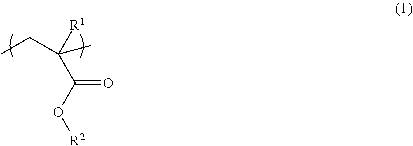
in the formula (1), R¹ is a hydrogen atom or a substituted or unsubstituted monovalent hydrocarbon group having 1 to 20 carbon atoms; and R² is a substituted or unsubstituted monovalent hydrocarbon group having 1 to 20 carbon atoms, 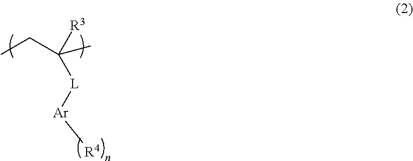
in the formula (2), R³ is a hydrogen atom or a substituted or unsubstituted monovalent hydrocarbon group having 1 to 20 carbon atoms; L is a single bond or a divalent linking group; Ar is a group obtained by removing (n+1) hydrogen atoms from a substituted or unsubstituted aromatic ring having 6 to 20 ring members; R⁴ is a monovalent hydroxyalkyl group having 1 to 10 carbon atoms or a hydroxy group; n is an integer of 0 to 8; and when n is 2 or more, a plurality of R⁴s are the same or different from each other.
